(19) United States
(12) Patent Application Publication
(10) Pub. No.: US 2025/0379039 A1
(43) Pub. Date: Dec. 11, 2025

(54) PLASMA PROCESSING APPARATUS

(71) Applicant: Samsung Display Co., LTD., Yongin-si (KR)

(72) Inventors: DONGHYUN KIM, Yongin-si (KR); SUKBEOM YOU, Yongin-si (KR); SOO BEOM JO, Yongin-si (KR)

(21) Appl. No.: 19/029,661

(22) Filed: Jan. 17, 2025

(30) Foreign Application Priority Data
Jun. 11, 2024 (KR) 10-2024-0075363

(51) Int. Cl. H01J 37/32

(52) U.S. Cl. CPC H01J 37/3244; H01J 37/3211; H01J 2237/3341

(57) ABSTRACT

A plasma processing apparatus includes a processing chamber providing a processing space in which a substrate is processed, a dielectric tube disposed above the processing chamber and providing an internal space, a gas supply which supplies a source gas to the internal space of the dielectric tube, a helical coil surrounding the dielectric tube, where the helical coil receives a high frequency power, and a blocking member disposed adjacent to the upper wall of the processing chamber. A first through hole is defined through an upper wall of the processing chamber, and the internal space of the dielectric tube communicates with the first through hole. A second through hole communicating with the first through hole is defined through the blocking member. A size of the second through hole is less than a size of the first through hole.

This application claims priority to Korean Patent Application No. 10-2024-0075363, filed on Jun. 11, 2024, and all the benefits accruing therefrom under 35 U.S.C. § 119, the content of which in its entirety is herein incorporated by reference.

### BACKGROUND

### 1. Field

Embodiments relate to a plasma processing apparatus. More particularly, embodiments relate to a plasma processing apparatus used in manufacturing a display device.

### 2. Description of the Related Art

Flat panel display devices are replacing cathode ray tube display devices as display devices due to their lightweight and thin characteristics. As representative examples of such flat panel display devices, there are liquid crystal display devices and organic light emitting diode display devices.

For manufacturing the flat panel display device, a process using plasma, such as an etching process, a deposition process, an ashing process, or the like may be performed. To obtain a plasma source for stably obtaining high-density and high-uniformity plasma in a low-temperature state, research into various plasma generating sources such as an inductively coupled plasma (“ICP”) source, an electron cyclotron resonance (“ECR”) plasma source, a helicon plasma source, a helical resonator-type plasma source, or the like, has been actively conducted.

### SUMMARY

In manufacturing a flat panel display device, when the plasma processing time becomes longer, such as when a plurality of substrates are processed continuously, the plasma generation from a plasma source may be reduced and a process efficiency of the plasma processing apparatus may be deteriorated.

Embodiments provide a plasma processing apparatus with improved process efficiency.

A plasma processing apparatus according to an embodiment includes a processing chamber providing a processing space in which a substrate is processed, a dielectric tube disposed above the processing chamber and providing an internal space, a gas supply which supplies a source gas to the internal space of the dielectric tube, a helical coil surrounding the dielectric tube, where the helical coil receives a high frequency power, and a blocking member disposed adjacent to the upper wall of the processing chamber. In such an embodiment, a first through hole is defined through an upper wall of the processing chamber, and the internal space of the dielectric tube communicates with the first through hole. In such an embodiment, a second through hole communicating with the first through hole is defined through the blocking member. In such an embodiment, a size of the second through hole is less than a size of the first through hole.

In an embodiment, the second through hole may be below a central area of the first through hole.

In an embodiment, the blocking member may be below a peripheral area of the first through hole surrounding the central area.

In an embodiment, in a plan view, each of the first through hole and the second through hole may have a circular shape, and a diameter of the second through hole may be less than a diameter of the first through hole.

In an embodiment, in a plan view, a center point of the second through hole may coincide with a center point of the first through hole.

In an embodiment, the upper wall of the processing chamber may include an upper surface facing the dielectric tube and a lower surface facing the substrate. In such an embodiment, the blocking member may be detachably attached to the lower surface of the upper wall.

In an embodiment, a fastening groove outside the first through hole and recessed upward from the lower surface of the upper wall may be defined in the upper wall. In such an embodiment, a fastening hole outside the second through hole may be defined through the blocking member.

In an embodiment, the plasma processing apparatus may further include a fastening member disposed through the fastening hole of the blocking member and inserted into the fastening groove of the upper wall.

In an embodiment, the upper wall of the processing chamber may include a side surface defining the first through hole. In such an embodiment, the blocking member may be detachably attached to the side surface of the upper wall.

In an embodiment, the side surface of the upper wall may have a first screw thread. In such an embodiment, an outer side surface of the blocking member may have a second screw thread corresponding to the first screw thread.

In an embodiment, the blocking member and the processing chamber may include a same material as each other.

In an embodiment, the blocking member may include a metal.

In an embodiment, the blocking member may have a mesh structure with a plurality of micro holes defined therethrough.

A plasma processing apparatus according to an embodiment includes a processing chamber providing a processing space in which a substrate is processed, a dielectric tube disposed above the processing chamber and providing an internal space, a gas supply which supplies a source gas to the internal space of the dielectric tube, a helical coil surrounding the dielectric tube, where the helical coil receives a high frequency power, and a blocking member disposed adjacent to the upper wall of the processing chamber and having a mesh structure with a plurality of micro holes defined therethrough. In such an embodiment, a through hole is defined through an upper wall of the processing chamber, and the internal space of the dielectric tube communicates with the through hole. In such an embodiment, the blocking member is disposed below an entire portion of the through hole.

In an embodiment, the upper wall of the processing chamber may include an upper surface facing the dielectric tube and a lower surface facing the substrate. In such an embodiment, the blocking member may be attached to the lower surface of the upper wall.

In an embodiment, a fastening groove outside the through hole and recessed upward from the lower surface of the upper wall may be defined in the upper wall. In such an embodiment, the blocking member may include a central portion below the through hole and an edge portion outside the central portion. In such an embodiment, a fastening hole may be defined through the edge portion of the blocking member.

In an embodiment, the plasma processing apparatus may further include a fastening member disposed through the fastening hole of the blocking member and inserted into the fastening groove of the upper wall.

In an embodiment, the upper wall of the processing chamber may include a side surface defining the through hole. In such an embodiment, the blocking member may be attached to the side surface of the upper wall.

In an embodiment, the side surface of the upper wall may have a first screw thread. In such an embodiment, an outer side surface of the blocking member may have a second screw thread corresponding to the first screw thread.

In an embodiment, the blocking member and the processing chamber may include a same material as each other.

According to embodiments of the disclosure, even when the plasma processing time becomes longer, such as when a plurality of substrates are processed continuously, the deterioration in the process efficiency of the plasma processing apparatus may be substantially reduced or effectively prevented.

It is to be understood that both the foregoing general description and the following detailed description are exemplary and explanatory and are intended to provide further explanation of the invention as claimed.

### BRIEF DESCRIPTION OF THE DRAWINGS

The above and other features of embodiments of the invention will become more apparent by describing in further detail embodiments thereof with reference to the accompanying drawings, in which:

FIG. 1 is a schematic cross-sectional view illustrating a plasma processing apparatus according to embodiments;

FIG. 2 is a schematic perspective view illustrating a dielectric tube and a helical coil included in the plasma processing apparatus of FIG. 1;

FIGS. 3A and 3B are cross-sectional views illustrating an embodiment of an area A of FIG. 1;

FIG. 4 is a rear view illustrating a blocking member of FIGS. 3A and 3B;

FIGS. 5A and 5B are cross-sectional views illustrating an embodiment of an area A of FIG. 1;

FIGS. 6A and 6B are cross-sectional views illustrating an embodiment of an area A of FIG. 1; and

FIGS. 7A and 7B are cross-sectional views illustrating an embodiment of an area A of FIG. 1.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element, it can be directly on the other element or intervening elements may be present therebetween. In contrast, when an element is referred to as being “directly on” another element, there are no intervening elements present.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting. As used herein, the singular forms “a,” “an” and “the” do not denote a limitation of quantity, and are intended to include the plural forms as well, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the specification, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another. Hereinafter, for example, a first direction may be the x-axis direction, a second direction may be the y-axis direction, and a third direction may be the z-axis direction.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings. The same reference numerals are used for the same components in the drawings, and any repetitive detailed descriptions of the same components will be omitted or simplified.

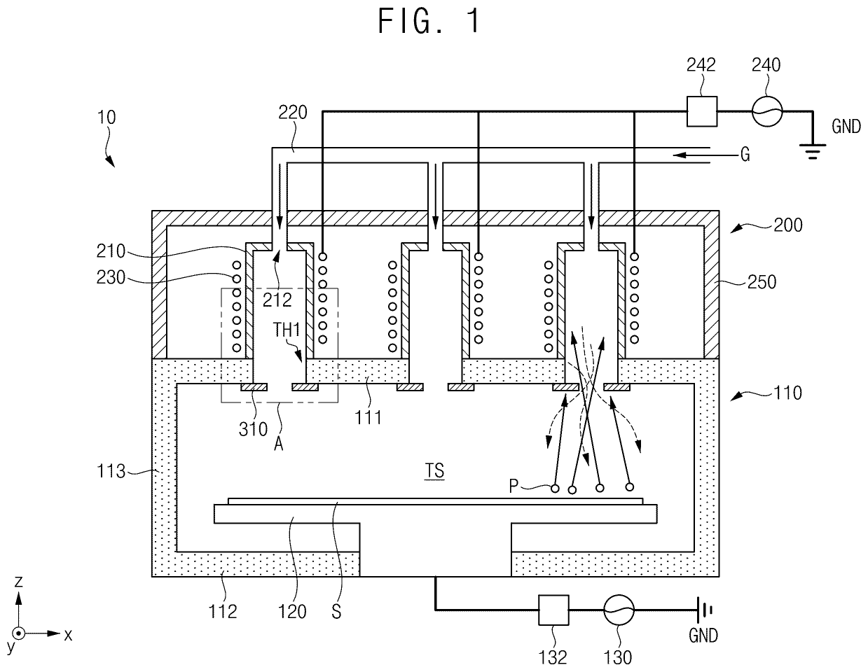

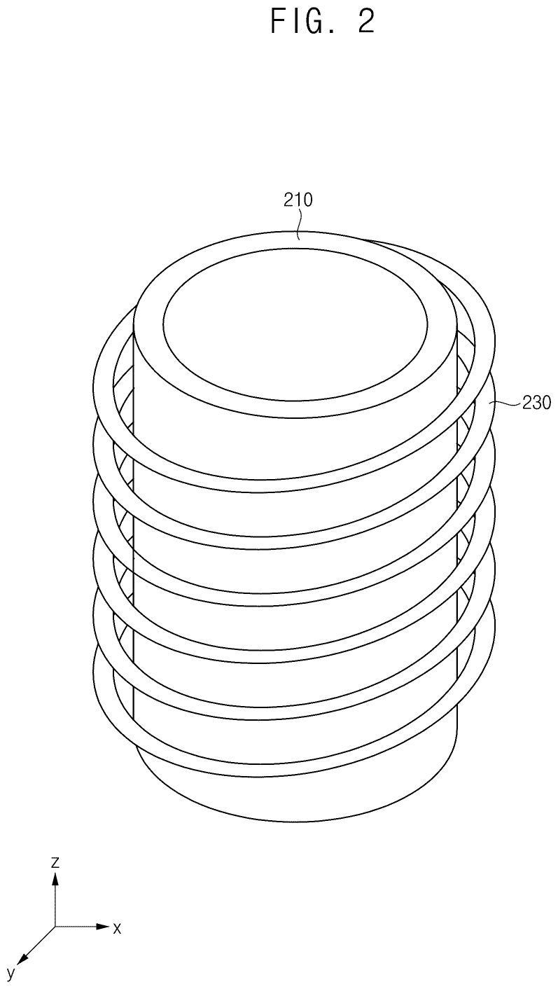

FIG. 1 is a schematic cross-sectional view illustrating a plasma processing apparatus according to embodiments. FIG. 2 is a schematic perspective view illustrating a dielectric tube and a helical coil included in the plasma processing apparatus of FIG. 1.

In embodiments, a plasma processing apparatus 10 is an apparatus for processing a substrate S, which is a processing target, using plasma. In an embodiment, for example, the processing of the substrate S may include (or may be) plasma etching, plasma annealing, sputtering, plasma cleaning, or the like. The substrate S may have a structure in which thin films and/or patterns formed of various materials, such as metal materials, insulating materials, semiconductor materials, or the like, are formed on various types of bases, such as a glass substrate, a semiconductor wafer, or the like. In an embodiment, for example, the substrate S may be a substrate in an intermediate stage of manufacturing a flat display device such as an organic light emitting display device, a liquid crystal display device, or the like, but this is an example and embodiments are not limited thereto.

In an embodiment, the processing of the substrate S may be a reactive ion etching. The reactive ion etching is a dry etching process in which excited species (radicals, ions) by a high frequency power (e.g., a radio frequency (“RF”) power) etch a substrate or a thin film in a low-pressure chamber. The plasma processing apparatus 10 may etch the thin films and/or the patterns formed from various materials, such as metal materials, insulating materials, semiconductor materials, or the like, by the reactive ion etching process.

Referring to FIGS. 1 and 2, the plasma processing apparatus 10 according to embodiments may include a processing chamber 110, a chuck 120, a plasma generator 200, and a blocking member 310.

The processing chamber 110 may provide or define a processing space TS in which the substrate S is processed. The processing chamber 110 may isolate the processing space TS from the outside. In an embodiment, for example, the processing chamber 110 may include a metal, such as aluminum, but this is an example and embodiments are not limited thereto.

In an embodiment, the processing chamber 110 may include an upper wall 111, a lower wall 112, and a side wall 113. The upper wall 111 may be spaced apart from the lower wall 112 in a third direction +z (hereinafter, an upward direction). The side wall 113 may connect the upper wall 111 and the lower wall 112 to each other or be connected between the upper wall 111 and the lower wall 112. The processing space TS may be defined in the processing chamber 110 by the upper wall 111, the lower wall 112, and the side wall 113.

The chuck 120 may support and fix the substrate S in the processing space TS. In an embodiment, for example, the chuck 120 may be an electrostatic chuck for fixing the substrate S with an electrostatic force, but this is an example and embodiments are not limited thereto. In another embodiment, for example, the chuck 120 may be a vacuum chuck that fixes the substrate S with vacuum pressure.

A power source 130 may be configured to supply power to the chuck 120. A matching network 132 may be connected between the power source 130 and the chuck 120. The matching network 132 may improve a transfer efficiency of power from the power source 130 to the chuck 120. In an embodiment, the power source 130 may supply, to the chuck 120, a clamping power for fixing the substrate S and/or a bias power for accelerating plasma to the substrate S.

In an embodiment, at least one first through hole TH1 may be defined through the upper wall 111. As described below, plasma generated from the plasma generator 200 may be transferred to the processing space TS through the first through hole TH1 to process the substrate S.

In an embodiment, the processing chamber 110 may include an inlet for supplying an additional process gas, an exhaust for discharging plasma and gas, or the like. The exhaust may be connected to a vacuum pump.

The plasma generator 200 may generate plasma, and may transfer the generated plasma to the processing space TS of the processing chamber 110. The plasma generator 200 may be configured to generate plasma based on a source gas G. In an embodiment, for example, the plasma generator 200 may be a helical resonator plasma source. In an embodiment, for example, the plasma generator 200 may be disposed above the processing chamber 110.

In an embodiment, the plasma generator 200 may include a dielectric tube 210, a gas supply 220, a helical coil 230, a high frequency power source 240, a matching network 242, and a housing 250.

The dielectric tube 210 may be disposed above the processing chamber 110. In an embodiment, for example, the dielectric tube 210 may include a dielectric material, such as quartz, ceramic, or the like.

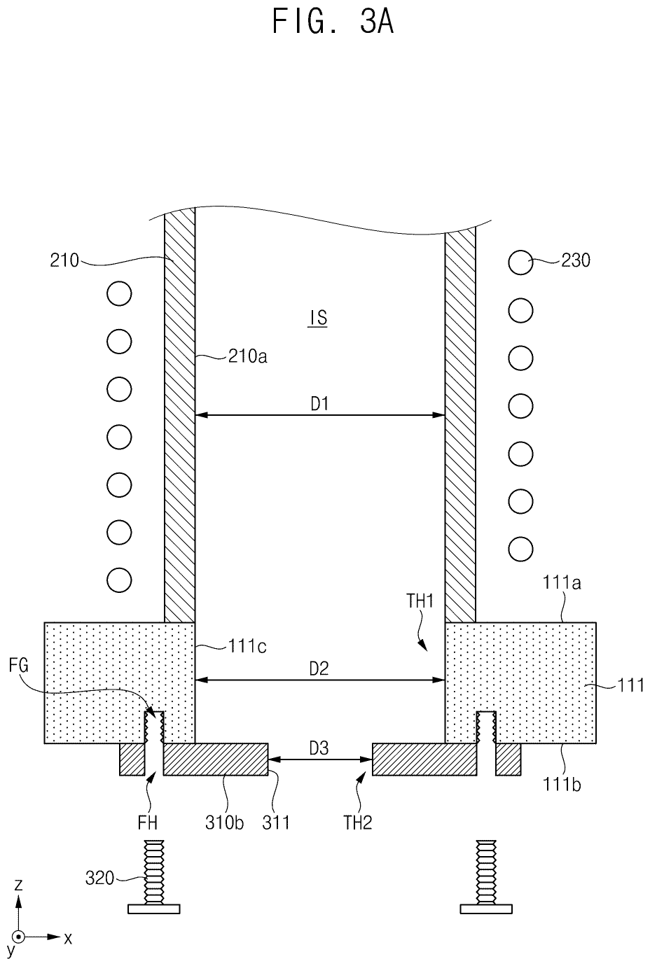

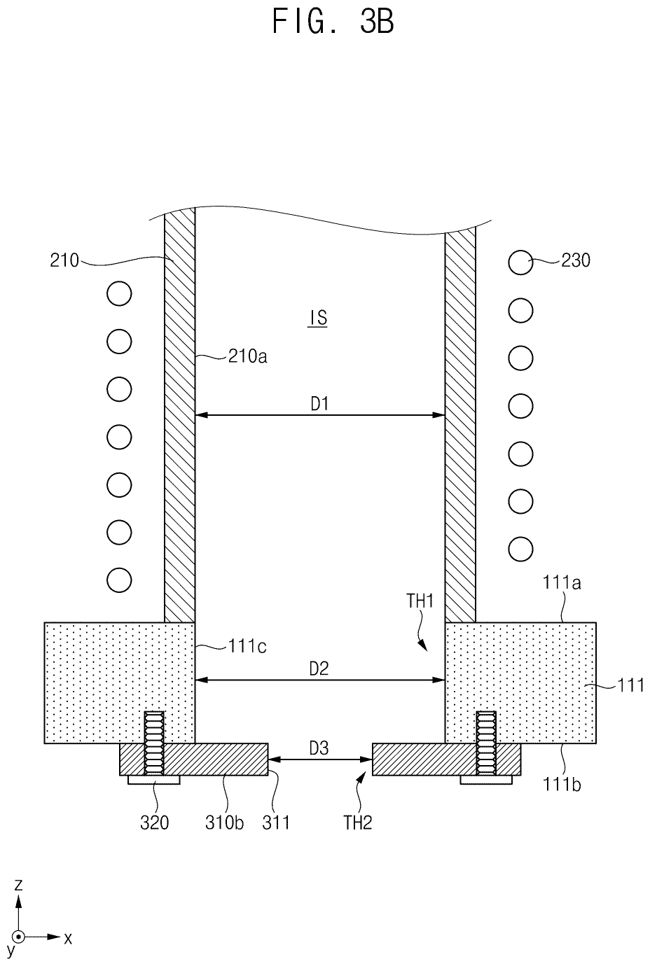

In an embodiment, the dielectric tube 210 may have a substantially cylindrical shape. The dielectric tube 210 may provide or define an internal space (an internal space IS of FIG. 3A). The dielectric tube 210 may be disposed on the upper wall 111 in a way such that the internal space may communicate with (or be connected to) the first through hole TH1. Accordingly, plasma generated in the internal space of the dielectric tube 210 may be transferred to the processing space TS of the processing chamber 110 through the first through hole TH1. In an embodiment, for example, radicals, ions, or the like of the plasma generated in the internal space of the dielectric tube 210 may move to the processing space TS of the processing chamber 110 through the first through hole TH1 by diffusion.

The dielectric tube 210 may include a gas inlet 212 for supplying the source gas G into the internal space. The gas inlet 212 may be connected to the gas supply 220. The gas supply 220 may be configured to supply the source gas G for generating plasma to the internal space of the dielectric tube 210 through the gas inlet 212.

In an embodiment, as illustrated in FIG. 2, the helical coil 230 may surround the dielectric tube 210. The helical coil 230 may be wound in a plurality of turns to have a spiral shape along an outer side surface of the dielectric tube 210.

The high frequency power source 240 may be configured to supply a high frequency power (e.g., RF power) to the helical coil 230. The matching network 242 may be connected between the high frequency power source 240 and the helical coil 230. The matching network 242 may improve a transfer efficiency of the high frequency power from the high frequency power source 240 to the helical coil 230.

When the high frequency power is applied to the helical coil 230, a time-varying magnetic field may be generated by a current flowing in the helical coil 230, and an electric field may be induced by the time-varying magnetic field. The induced electric field may ionize the source gas G to generate a high-density plasma.

In an embodiment, as illustrated in FIG. 1, the plasma generator 200 may include a plurality of dielectric tubes 210 and a plurality of helical coils 230 for generating plasma. In an embodiment, for example, the plurality of dielectric tubes 210 may be arranged in an array form along a first direction +x and a second direction +y, and the plurality of helical coils 230 may surround the plurality of dielectric tubes 210, respectively. In addition, a plurality of first through holes TH1, respectively corresponding to the plurality of dielectric tubes 210, may be defined through the upper wall 111 of the processing chamber 110. As the number of dielectric tubes 210 and helical coils 230 increases, a large-sized substrate S may be efficiently processed. In another embodiment, the plasma generator 200 may include a single dielectric tube 210 and a single helical coil 230 surrounding the single dielectric tube 210.

The housing 250 may accommodate the dielectric tube 210 and the helical coil 230 therein. In an embodiment, for example, the housing 250 may include a metal. The housing 250 may protect the dielectric tube 210 and the helical coil 230 and may block electromagnetic waves.

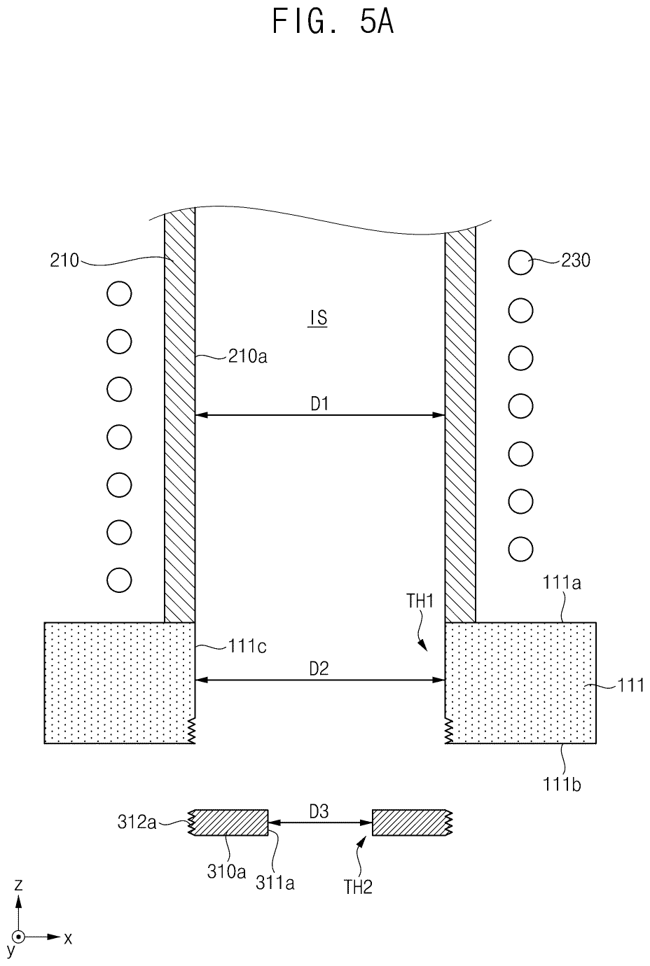

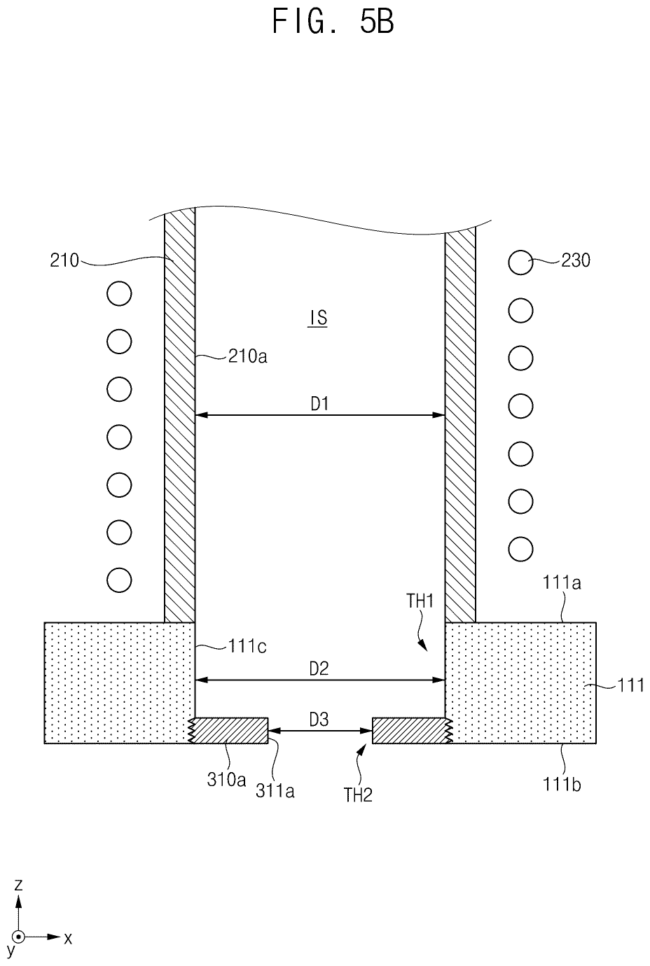

The blocking member 310 may be disposed adjacent to the upper wall 111 of the processing chamber 110. In an embodiment, the blocking member 310 may be disposed on a lower surface of the upper wall 111 adjacent to the first through hole TH1 (see FIG. 3B) or may be disposed in the first through hole TH1 (see FIG. 5B), but embodiments are not limited thereto. In an embodiment, as illustrated in FIG. 1, where each of the dielectric tube 210 and the helical coil 230 is provided in plurality and a plurality of first through holes TH1, respectively corresponding to the plurality of dielectric tubes 210, are defined through the upper wall 111, a plurality of blocking members 310 may be disposed corresponding to the first through holes TH1, respectively.

In an embodiment, as illustrated in FIG. 1, when the substrate S is processed, particles P, such as metal particles, separated from the substrate S, may be linearly moved and flow into the internal space of the dielectric tube 210. In a comparative example in which the blocking member 310 does not exist, when the processing time of the substrate S becomes longer, a large amount of particles P flow into the internal space of the dielectric tube 210, and a metal thin film, etc. may be formed on an inner side surface of the dielectric tube 210 (an inner side surface 210a of FIG. 3A). In this case, the metal thin film may shield the electromagnetic wave generated from the helical coil 230, such that plasma generation in the internal space of the dielectric tube 210 may be reduced, and a process efficiency of the plasma processing apparatus 10 may be deteriorated.

In the plasma processing apparatus 10 according to embodiments, the blocking member 310, which at least partially covers the first through hole TH1, may control or reduce particles P, such as metal particles, from flowing into the internal space of the dielectric tube 210 through the first through hole TH1 (see a solid arrow of FIG. 1). Accordingly, a formation of a metal thin film, etc. on the inner side surface of the dielectric tube 210 may be reduced. Thus, even when the processing time of the substrate S becomes longer (e.g., even when a plurality of substrates S are processed continuously), the deterioration in the process efficiency of the plasma processing apparatus 10 may be reduced. In such embodiments, as described above, because the radicals, ions, or the like of the plasma generated from the internal space of the dielectric tube 210 move to the processing space TS of the processing chamber 110 through the first through hole TH1 by diffusion, the blocking member 310 may not interfere the plasma from being transferred to the processing space TS (see a dotted arrow of FIG. 1). In such embodiments, because a pressure of the internal space of the dielectric tube 210 may increase due to the blocking member 310, a pressure difference between the internal space of the dielectric tube 210 and the processing space TS of the processing chamber 110 may increase. Accordingly, the diffusion of the radicals, ions, or the like of the plasma from the internal space of the dielectric tube 210 to the processing space TS may occur more actively. Therefore, even when the processing time of the substrate S becomes longer, the deterioration in the process efficiency of the plasma processing apparatus 10 may be further reduced.

In an embodiment, the blocking member 310 and the processing chamber 110 may include a same material as each other. In an embodiment, for example, the blocking member 310 may include a metal, such as aluminum, but this is an example and embodiments are not limited thereto. In another embodiment, the blocking member 310 may include a different material from the processing chamber 110.

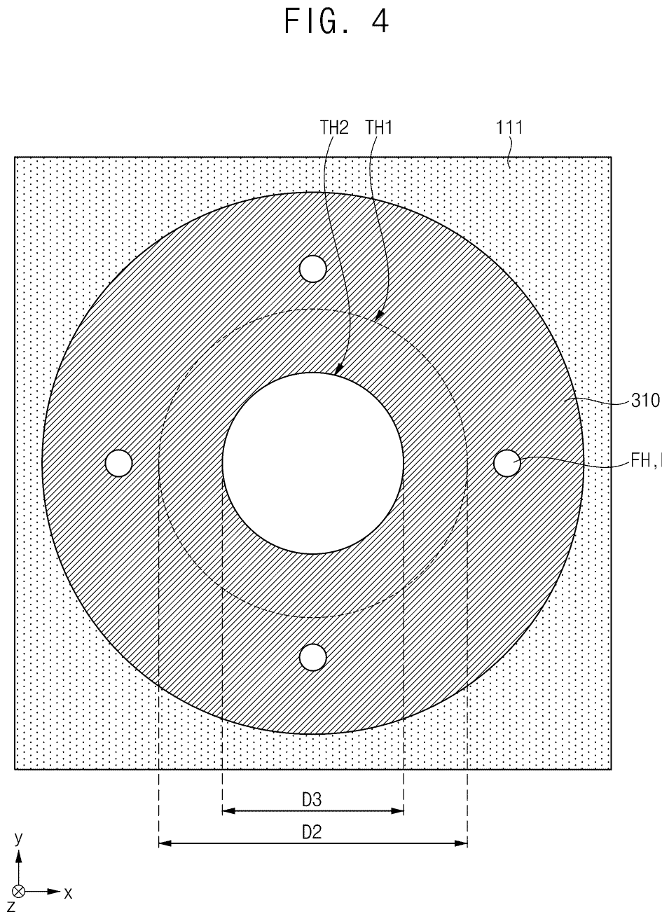

FIGS. 3A and 3B are cross-sectional views illustrating an embodiment of an area A of FIG. 1. FIG. 4 is a rear view illustrating a blocking member of FIGS. 3A and 3B.

Referring to FIGS. 1, 3A, 3B, and 4, in an embodiment, the upper wall 111 of the processing chamber 110 may include an upper surface 111a facing the dielectric tube 210, a lower surface 111b facing the chuck 120 (or facing the substrate S), and a side surface (or an inner side surface) 111c defining the first through hole TH1. The dielectric tube 210 may be disposed on the upper surface 111a of the upper wall 111. The blocking member 310 may be disposed on the lower surface 111b of the upper wall 111.

In an embodiment, the first through hole TH1 of the upper wall 111 may have a shape corresponding to the internal space IS of the dielectric tube 210. In an embodiment, for example, in a plan view, each of the internal space IS of the dielectric tube 210 and the first through hole TH1 of the upper wall 111 may have a circular shape.

In an embodiment, in a plan view, a size of the first through hole TH1 may be equal to a size of the inner space IS of the dielectric tube 210. In an embodiment, for example, a diameter D1 of the inner space IS of the dielectric tube 210 may be equal to a diameter D2 of the first through hole TH1. In an embodiment, for example, in a cross-sectional view, the inner side surface 210a of the dielectric tube 210 and the side surface 111c of the upper wall 111 may be aligned with (or on a same plane as) each other.

In an embodiment, a second through hole TH2 may be defined through the blocking member 310. The second through hole TH2 may be defined by an inner side surface 311 of the blocking member 310. The blocking member 310 may be disposed adjacent to the upper wall 111 of the processing chamber 110 in a way such that the second through hole TH2 may communicate with the first through hole TH1. That is, all the inner space IS of the dielectric tube 210, the first through hole TH1, the second through hole TH2, and the processing space TS of the processing chamber 110 may be communicated with each other.

In a plan view, a size of the second through hole TH2 of the blocking member 310 may be less than the size of the first through hole TH1 of the upper wall 111. In a plan view, the first through hole TH1 of the upper wall 111 may include a central area and a peripheral area surrounding the central area. The blocking member 310 may be disposed on the lower surface 111b of the upper wall 111 in a way such that the second through hole TH2 may be below (or to overlap) the central area of the first through hole TH1. The blocking member 310 may be disposed on the lower surface 111b of the upper wall 111 in a way such that the blocking member 310 may be below (or to overlap) the peripheral area of the first through hole TH1. The inner side surface 311 of the blocking member 310 may be positioned inwardly (e.g., in a direction toward a center point of the first through hole TH1 or a center point of the second through hole TH2) from the side surface 111c of the upper wall 111.

In an embodiment, the first through hole TH1 may have a planar shape corresponding to a planar shape of the second through hole TH2. In an embodiment, for example, as illustrated in FIG. 4, in a plan view, each of the first through hole TH1 and the second through hole TH2 may have a circular shape. In a plan view, a diameter D3 of the second through hole TH2 may be less than the diameter D2 of the first through hole TH1. In an embodiment, for example, as illustrated in FIG. 4, the blocking member 310 may be disposed on the lower surface 111b of the upper wall 111 in a way such that the center point of the second through hole TH2 may coincide with the center point of the first through hole TH1 in a plan view.

The blocking member 310 may be attached (e.g., fastened or coupled) to the lower surface 111b of the upper wall 111 to be replaceable. That is, the blocking member 310 may be detachably attached to the lower surface 111b of the upper wall 111.

In an embodiment, a fastening groove FG may be defined in the upper wall 111 and outside (or not to overlap) the first through hole TH1 in a plan view. The fastening groove FG may be recessed in the third direction +z (the upward direction) from the lower surface 111b of the upper wall 111.

A fastening hole FH corresponding to the fastening groove FG may be defined through the blocking member 310. The fastening hole FH may be located outside (or not to overlap) the second through hole TH2 in a plan view. The fastening hole FH may pass through the blocking member 310 in the third direction +Z.

In an embodiment, as illustrated in FIG. 4, each of the fastening groove FG and the fastening hole FH may be provided in plurality. FIG. 4 illustrates an embodiment where four fastening grooves FG are defined outside the first through hole TH1, and correspondingly, four fastening holes FH are defined outside the second through hole TH2, but the number of fastening grooves FG and fastening holes FH may be variously changed.

The plasma processing apparatus 10 may further include a fastening member 320 for fastening the blocking member 310 to the upper wall 111 of the processing chamber 110. The fastening member 320 may be disposed through or penetrating the fastening hole FH of the blocking member 310 and may be inserted into the fastening groove FG of the upper wall 111. In an embodiment, a side surface, which defines the fastening groove FG, of the upper wall 111 may have a first screw thread, and a portion, which is inserted into the fastening groove FG, of the fastening member 320 may have a second screw thread corresponding to the first screw. The number of fastening members 320 may be equal to each of the number of fastening grooves FG and the number of fastening holes FH. The blocking member 310 may be attached or fastened to the lower surface 111b of the upper wall 111, through the fastening member 320, to be replaceable. That is, the blocking member 310 may be detachably attached to the lower surface 111b of the upper wall 111.

In an embodiment, for example, the optimal diameter D3 of the second through hole TH2 of the blocking member 310, which is selected to effectively reduce the deterioration in the process efficiency of the plasma processing apparatus 10, may vary depending on a material of the source gas G, a material of the thin film to be etched, or the like.

In an embodiment, various blocking members 310 respectively defining second through holes TH2 of various diameters D3 may be prepared. Before processing of the substrate S, considering a material of the source gas G, a material of the thin film to be etched, or the like, one of the various blocking members 310, which defines the second through hole TH2 of the optimal diameter D3, may be attached or fastened to the lower surface 111b of the upper wall 111, and thereafter, the substrate S may be processed. In another embodiment, the blocking member 310 may be configured in a way such that the diameter D3 of the second through hole TH2 may be variously adjusted.

FIGS. 5A and 5B are cross-sectional views illustrating an embodiment of an area A of FIG. 1.

Hereinafter, embodiments of FIGS. 5A and 5B will be described with a focus on differences from the embodiments described above with reference to FIGS. 3A and 3B, and any repetitive detailed descriptions of the same or like elements as those described above will be omitted or simplified.

Referring to FIGS. 1, 5A and 5B, in an embodiment, the blocking member 310a may be disposed in the first through hole TH1 of the upper wall 111. In an embodiment, for example, the blocking member 310a may be attached (e.g., fastened or coupled) to the side surface 111c, which defines the first through hole TH1, of the upper wall 111 to be replaceable. That is, the blocking member 310a may be detachably attached to the side surface 111c of the upper wall 111.

In an embodiment, at least a portion of the side surface 111c of the upper wall 111 may have the first screw thread. In an embodiment, for example, as illustrated in FIG. 5A, a lower portion of the side surface 111c of the upper wall 111 may have the first screw thread. An outer side surface 312a of the blocking member 310a may have the second screw thread corresponding to the first screw thread. Therefore, the blocking member 310a may be attached or fastened to the side surface 111c, which defines the first through hole TH1, of the upper wall 111 to be replaceable. That is, the blocking member 310a may be detachably attached to the side surface 111c of the upper wall 111.

In an embodiment, various blocking members 310a respectively defining second through holes TH2 of various diameters D3 may be prepared. Before processing of the substrate S, considering a material of the source gas G, a material of the thin film to be etched, or the like, one of the various blocking members 310a, which defines the second through hole TH2 of the optimal diameter D3, may be attached or fastened to the side surface 111c of the upper wall 111, and thereafter, the substrate S may be processed. In another embodiment, the blocking member 310a may be configured in a way such that the diameter D3 of the second through hole TH2 may be variously adjusted.

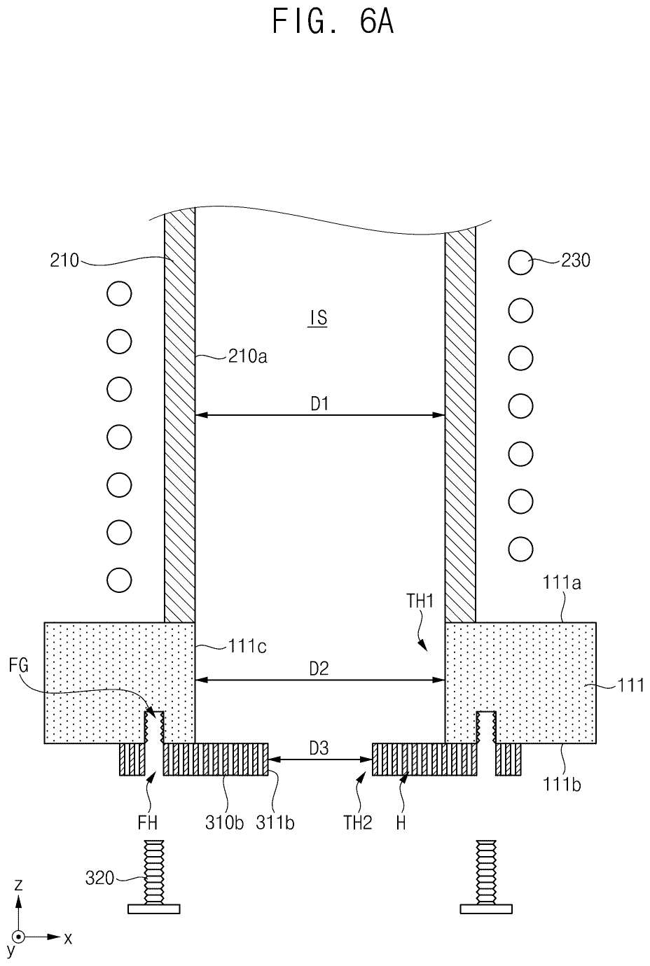

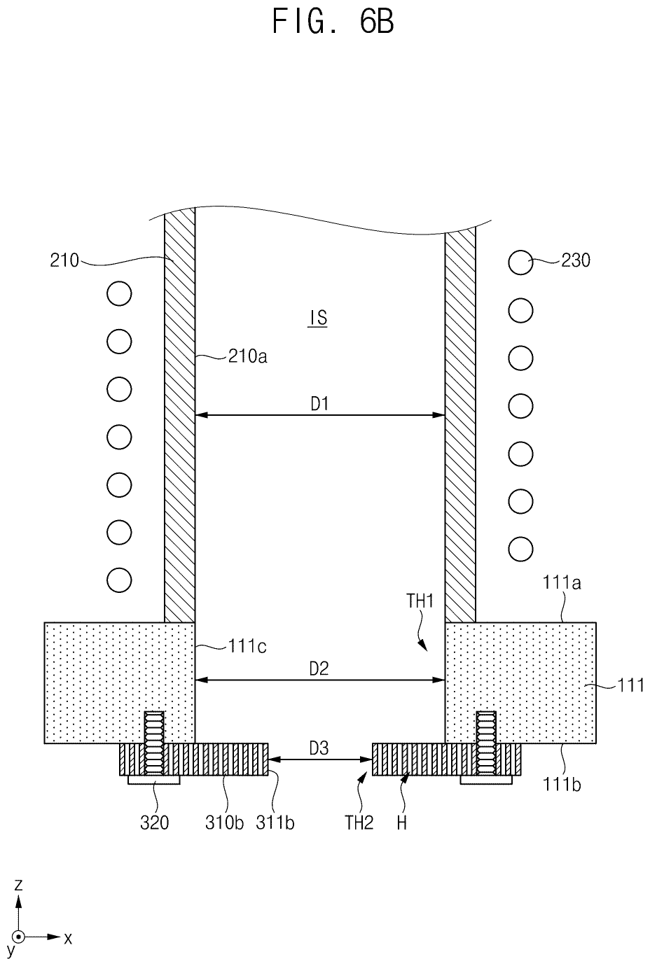

FIGS. 6A and 6B are cross-sectional views illustrating an embodiment of an area A of FIG. 1.

Hereinafter, embodiments of FIGS. 6A and 6B will be described with a focus on differences from the embodiments described above with reference to FIGS. 3A and 3B, and any repetitive detailed descriptions of the same or like elements as those described above will be omitted or simplified.

Referring to FIGS. 1, 6A, and 6B, in an embodiment, the second through hole TH2 may be defined through the blocking member 310b. In addition, the blocking member 310b may have a fine mesh structure with a plurality of fine holes H defined therethrough. The fine holes H may block the movement of particles P, such as metal particles, and may not interfere with the diffusion of radicals, ions, or the like of the plasma. Accordingly, the deterioration in the process efficiency of the plasma processing apparatus 10 may be further reduced.

In an embodiment, the blocking member 310b may be attached (e.g., fastened or coupled) to the lower surface 111b of the upper wall 111, through the fastening member 320, to be replaceable. In another embodiment, like the embodiments of FIGS. 5A and 5B, the blocking member 310b may be attached (e.g., fastened or coupled) to the side surface 111c of the upper wall 111 to be replaceable. That is, the blocking member 310b may be detachably attached to the side surface 111c of the upper wall 111.

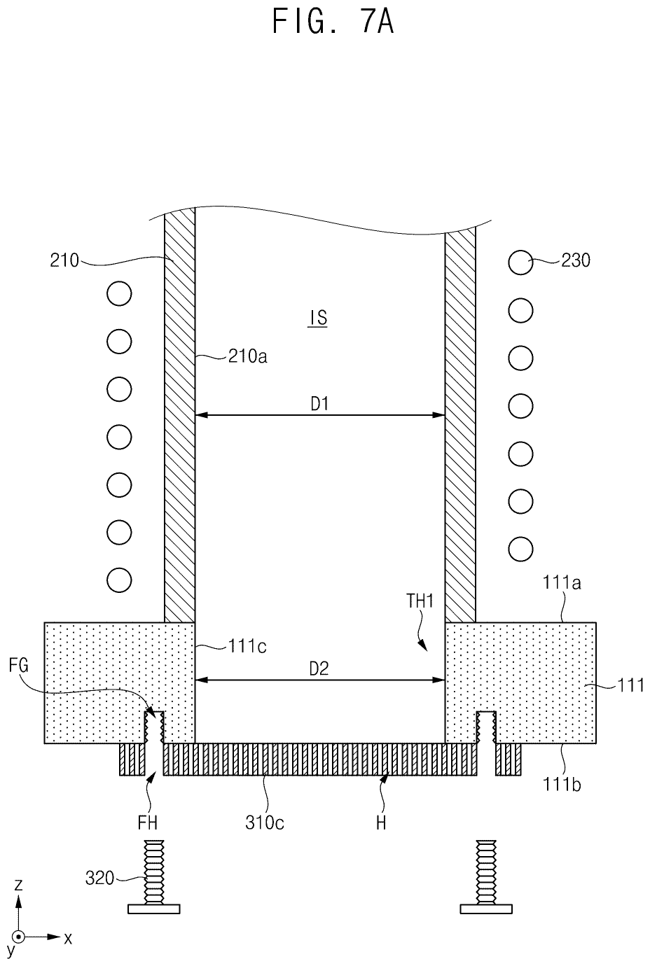

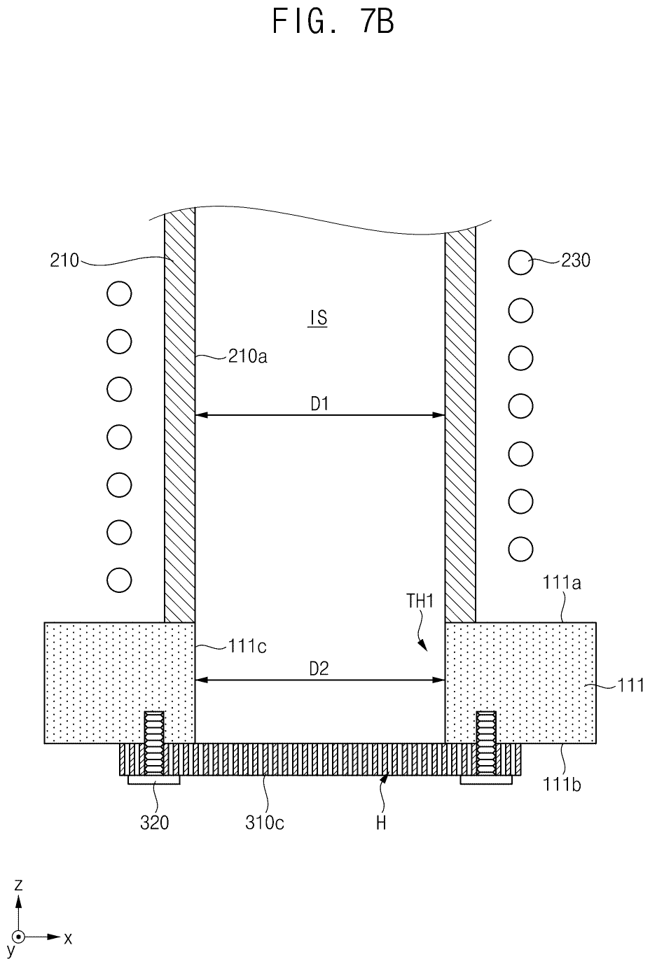

FIGS. 7A and 7B are cross-sectional views illustrating an embodiment of an area A of FIG. 1.

Hereinafter, embodiments of FIGS. 7A and 7B will be described with a focus on differences from the embodiments described above with reference to FIGS. 3A and 3B, and any repetitive detailed descriptions of the same or like elements as those described above will be omitted or simplified.

Referring to FIGS. 1, 7A, and 7B, in an embodiment, the blocking member 310c may have a fine mesh structure with a plurality of fine holes H defined therethrough. The blocking member 310c may be disposed adjacent to the upper wall 111 of the processing chamber 110 to be below (to cover) the entire portion of the first through hole TH1. That is, the fine mesh structure of the blocking member 310c may overlap the entire portion of the first through hole TH1 in a plan view. That is, the blocking member 310c may not define the second through hole TH2 of FIGS. 3A and 3B. In such an embodiment where the blocking member 310c does not define the second through hole TH2, radicals, ions, or the like of the plasma may diffuse from the internal space IS of the dielectric tube 210 to the processing space TS of the processing chamber 110 through the fine holes H. In such an embodiment, particles P, such as metal particles, may be blocked by the blocking member 310c from linearly moving and flowing into the internal space IS of the dielectric tube 210. Therefore, even when the processing time of the substrate S becomes longer, the deterioration in the process efficiency of the plasma processing apparatus 10 may be further reduced.

In an embodiment, the blocking member 310c may be attached (e.g., fastened or coupled) to the lower surface 111b of the upper wall 111, through the fastening member 320, to be replaceable. In another embodiment, e.g., the embodiments of FIGS. 5A and 5B, the blocking member 310c may be attached (e.g., fastened or coupled) to the side surface 111c of the upper wall 111 to be replaceable. That is, the blocking member 310c may be detachably attached to the side surface 111c of the upper wall 111.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A plasma processing apparatus comprising:
a processing chamber providing a processing space, in which a substrate is processed, wherein a first through hole is defined through an upper wall of the processing chamber;
a dielectric tube disposed above the processing chamber and providing an internal space communicating with the first through hole;
a gas supply which supplies a source gas to the internal space of the dielectric tube;
a helical coil surrounding the dielectric tube, wherein the helical coil receives a high frequency power; and
a blocking member disposed adjacent to the upper wall of the processing chamber,
wherein a second through hole communicating with the first through hole is defined through the blocking member, and
wherein a size of the second through hole is less than a size of the first through hole.

2. The plasma processing apparatus of claim 1, wherein the second through hole is below a central area of the first through hole.

3. The plasma processing apparatus of claim 2, wherein the blocking member is below a peripheral area of the first through hole surrounding the central area.

4. The plasma processing apparatus of claim 1, wherein in a plan view,
each of the first through hole and the second through hole has a circular shape, and
a diameter of the second through hole is less than a diameter of the first through hole.

5. The plasma processing apparatus of claim 4, wherein in a plan view, a center point of the second through hole coincides with a center point of the first through hole.

6. The plasma processing apparatus of claim 1, wherein
the upper wall of the processing chamber includes an upper surface facing the dielectric tube and a lower surface facing the substrate, and
the blocking member is detachably attached to the lower surface of the upper wall.

7. The plasma processing apparatus of claim 6, wherein
a fastening groove outside the first through hole and recessed upward from the lower surface of the upper wall is defined in the upper wall, and
a fastening hole outside the second through hole is defined through the blocking member.

8. The plasma processing apparatus of claim 7, further comprising:
a fastening member disposed through the fastening hole of the blocking member and inserted into the fastening groove of the upper wall.

9. The plasma processing apparatus of claim 1, wherein
the upper wall of the processing chamber includes a side surface defining the first through hole, and
the blocking member is detachably attached to the side surface of the upper wall.

10. The plasma processing apparatus of claim 9, wherein
the side surface of the upper wall has a first screw thread, and
an outer side surface of the blocking member has a second screw thread corresponding to the first screw thread.

11. The plasma processing apparatus of claim 1, wherein the blocking member and the processing chamber include a same material as each other.

12. The plasma processing apparatus of claim 1, wherein the blocking member includes a metal.

13. The plasma processing apparatus of claim 1, wherein the blocking member has a mesh structure with a plurality of micro holes defined therethrough.

14. A plasma processing apparatus comprising:
a processing chamber providing a processing space in which a substrate is processed, wherein a through hole is defined through an upper wall of the processing chamber;
a dielectric tube disposed above the processing chamber and providing an internal space communicating with the through hole;
a gas supply which supplies a source gas to the internal space of the dielectric tube;
a helical coil surrounding the dielectric tube, wherein the helical coil receives a high frequency power; and
a blocking member disposed adjacent to the upper wall of the processing chamber, disposed below an entire portion of the through hole, and having a mesh structure with a plurality of micro holes defined therein.

15. The plasma processing apparatus of claim 14, wherein
the upper wall of the processing chamber includes an upper surface facing the dielectric tube and a lower surface facing the substrate, and
the blocking member is attached to the lower surface of the upper wall.

16. The plasma processing apparatus of claim 15, wherein
a fastening groove outside the through hole and recessed upward from the lower surface of the upper wall is defined in the upper wall,
the blocking member includes a central portion below the through hole and an edge portion outside the central portion, and
a fastening hole is defined through the edge portion of the blocking member.

17. The plasma processing apparatus of claim 16, further comprising:
a fastening member disposed through the fastening hole of the blocking member and inserted into the fastening groove of the upper wall.

18. The plasma processing apparatus of claim 14, wherein
the upper wall of the processing chamber includes a side surface defining the through hole, and
the blocking member is attached to the side surface of the upper wall.

19. The plasma processing apparatus of claim 18, wherein
the side surface of the upper wall has a first screw thread, and
an outer side surface of the blocking member has a second screw thread corresponding to the first screw thread.

20. The plasma processing apparatus of claim 14, wherein the blocking member and the processing chamber include a same material as each other.
